(19) United States
(12) Patent Application Publication
(10) Pub. No.: US 2016/0251551 A1
(43) Pub. Date: Sep. 1, 2016

(54) FRAME SEALANT AND METHOD OF PREPARING THE SAME AND DISPLAY DEVICE COMPRISING SAID FRAME SEALANT

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Jian WANG, Beijing (CN); Wei LI, Beijing (CN)

(21) Appl. No.: 14/386,491

(22) PCT Filed: Dec. 30, 2013
(86) PCT No.: PCT/CN2013/090927

§ 371 Date: Sep. 19, 2014

(30) Foreign Application Priority Data
Jul. 8, 2013 (CN) 201310284754.X

(51) Int. Cl. C09J 133/08; G02F 1/1339; G02F 1/1335; G02B 5/20

(52) U.S. Cl. CPC C09J 133/08; G02B 5/201; G02F 1/1339; G02F 1/133514; C23C 16/458

(57) ABSTRACT

A frame sealant and a method of preparing the same as well as a display device containing the frame sealant. The frame sealant includes an epoxy-acrylic resin, an acrylic resin, a thermal curing agent, a coupling agent, a photoinitiator, and an organic filler, and further an one-dimensional nano-material as an inorganic filler which is capable of cross-linking with the epoxy-acrylic resin. The one-dimensional nano-material after cross-linking with the epoxy-acrylic resin will form an interlaced network, which can prevent granular materials from precipitating and improve the display quality.

### TECHNICAL FIELD

Embodiments of the present invention relate to a frame sealant and a method of preparing the same as well as a display device comprising the frame sealant.

### BACKGROUND

The liquid crystal display panel achieves a rapid development as the progress of science. The liquid crystal display panel determines to a great extent the lightness, contrast, color, and view angle of the liquid crystal display device. Therefore, the process for manufacturing the liquid crystal display panel will directly influence the quality of the display.

Current liquid crystal display panel is generally formed from cell assembly of a array substrate and a color film substrate. FIG. 1 shows a schematic diagram of a cross-section construction of the prior liquid crystal panel, which comprises an array substrate 1, a color film substrate 2, and a liquid crystal 4 and a frame sealant 3 provided between the array substrate 1 and the color film substrate 2. When the array substrate 1 and the color film substrate 2 are cell assembled, they are attached together to form an integrated liquid crystal panel by using the frame sealant 3 as an adhesive and seal the liquid crystal 4 drop filled between them via the frame sealant 3. Therefore, the frame sealant is a key component during the fabrication of liquid crystal display panels.

The inorganic fillers for use in the current frame sealants typically contain silica nano-particles as main components, which will exhibit certain bonding strength after curing, capable of serving as a support. However, during the process of curing the frame sealant and cell assembly of array substrate and color film substrate, granular precipitates are usually produced. The inorganic fillers containing silica nano-particles as main components can serve as a good support, but they could not prevent the granular precipitates from separating out, and the separated granular precipitates would easily cause afterimiage during image display and lead to poor display. The embodiments of the present invention aim to provide a frame sealant and a method of preparing and curing the same, a display device sealed with the frame sealant to address the problem that the frame sealant cannot prevent the granular precipitates from separating out, causing poor display.

### SUMMARY

An embodiment of the present invention provides a frame sealant, which comprises an epoxy-acrylic resin, an acrylic resin, a thermal curing agent, a coupling agent, a photoinitiator, and an organic filler, and further an one-dimensional nano-material as an inorganic filler which is capable of cross-linking with the epoxy-acrylic resin.

The one-dimensional nano-material is zinc oxide nanowires.

The one-dimensional nano-material is 10-20% by weight.

The zinc oxide nanowires have an outer diameter of 5-20 nm and a length of 50-500 nm.

An embodiment of the present invention further provides a display device, comprising an array substrate and a color film substrate cell assembled, between which the frame sealant is provided.

An embodiment of the present invention further provides a method of preparing the frame sealant, comprising:
Mixing 10-20 wt % of an one-dimensional nano-material, 20-30 wt % of an epoxy-acrylic resin, 30-40 wt % of an acrylic resin, 10-20 wt % of a thermal curing agent, 4-5 wt % of a coupling agent, 0.1-1 wt % of a photoinitiator, and 1-10 wt % of an organic filler for 30-60 min at a temperature of 10-30° C., to form a stirred mixture;
compounding the stirred mixture;
debubbling the compounded mixture.

The one-dimensional nano-material is zinc oxide nanowires or carbon nanowires.

Prior to forming a stirred mixture, the method further comprises:
preparing the zinc oxide nanowires from zinc powder and manganese oxide powder by a chemical vapor deposition process.

Here, preparing the zinc oxide nanowires from zinc powder and manganese oxide powder by a chemical vapor deposition process comprises:
continuously passing a mixed gas of oxygen and argon into zinc powder and manganese oxide powder in a weight ratio of 9:1 at a temperature of 600-700° C. for reacting for 20-40 min, to produce the zinc oxide nanowires.

Here, argon is passed in a flow rate of 300-320 cm³·min⁻¹ and oxygen is passed in a flow rate of 10-15 cm³·min⁻¹.

### BRIEF DESCRIPTION OF THE DRAWINGS

FIG. 1 shows a schematic view of the construction of the prior liquid crystal display panel;

FIG. 2 shows a schematic view of the structure of an interlaced network structure formed in the examples of the present invention;

FIG. 3 shows a schematic view of preparing the zinc oxide nanowires according to the examples of the present invention;

FIG. 4 shows a flow chart of preparing the frame sealant according to the examples of the present invention.

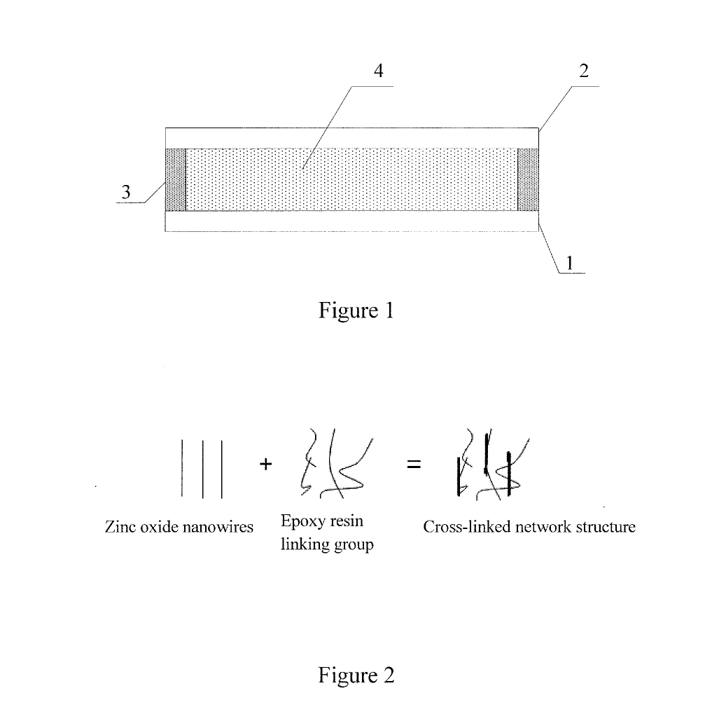

### DETAILED DESCRIPTION

The embodiments of the present invention will be described clearly and completely hereinafter. It is apparent that the described embodiments represent only a portion of, rather than all of the embodiments of the present invention. Based on the embodiments of the present invention, persons of ordinary skill in the art can obtain other embodiments without creative work, all of which are encompassed within the present invention.

### Example 1

The frame sealant according to the example of the present invention comprises an epoxy-acrylic resin, an acrylic resin, a thermal curing agent, a coupling agent, a photoinitiator, and an organic filler, and further an one-dimensional nano-material as an inorganic filler which is capable of cross-linking with the epoxy-acrylic resin to form an interlaced network.

Particularly, the epoxy-acrylic resin has a cross-linking group. When taking the one-dimensional nano-material as the inorganic filler, a cross-linking reaction occurs between the one-dimensional nano-material and the epoxy-acrylic resin, to form an interlaced network, which can prevent granular materials from precipitating and improve the display quality. The epoxy-acrylic resin can be any of the epoxy-acrylic resins known in the art for such purpose, which, for example can be commercially available from Showa Highpolymer Co., Ltd., Tianhongyunda, Najing Jingwen Chemical., etc.

In the example of the present invention, zinc oxide nanowires are preferably used as an inorganic filler to replace the silica nano-particles used as filler in the frame sealant. Since the method of preparing the zinc oxide nanowires is low cost and easy, it could be widely spread. The one-dimensional nano-materials are not particularly limited, as long as they can perform a cross-linking reaction with the epoxy-acrylic resin to form an interlaced network. For example, the one-dimensional nano-material also can be carbon nanowires.

In the example of the present example, zinc oxide nanowires can cross-link with the cross-linking group in the epoxy-acrylic resin, as shown in FIG. 2, which illustrates the cross-linking reaction between zinc oxide nanowires and the epoxy-acrylic resin. After zinc oxide nanowires cross-link with the cross-linking group in the epoxy-acrylic resin, an interlaced network structure will be formed. Such network structure homogenously interlaces with the resins in the frame resin, which will increase the adhesion as compared to conventional frame sealant, can prevent the matter from separating out and effectively improve adverse precipitation phenomena occurring in the frame sealant.

Further, in the example of the present invention, zinc oxide nanowires are used as an inorganic filler. When irradiating the frame sealant comprising zinc oxide nanowires with an UV light to perform an UV cuing, zinc oxide nanowires can act as a photocatalyst to facilitate the curing rate of the epoxy structure material. The common zinc oxide materials are inorganic nonmetallic ones and are insensitive to irradiation, while zinc oxides in nanowires structure, upon UV irradiation, will undergo charge carrier transfer, generate electricity and then generate heat, and facilitate the curing of the epoxy-acrylic resin.

Zinc oxide nanowires should not be too large or too small in size. If the size is too large, zinc oxide nanowires could not be evenly dispersed in the frame sealant composition and would reduce the adhesion thereof. If the size is too small, the cost would be increased and is not economical. Therefore, in the example of the present invention, zinc oxide nanowires as the inorganic filler preferably have an outer diameter of 5-20 nm and a length of 50-500 nm.

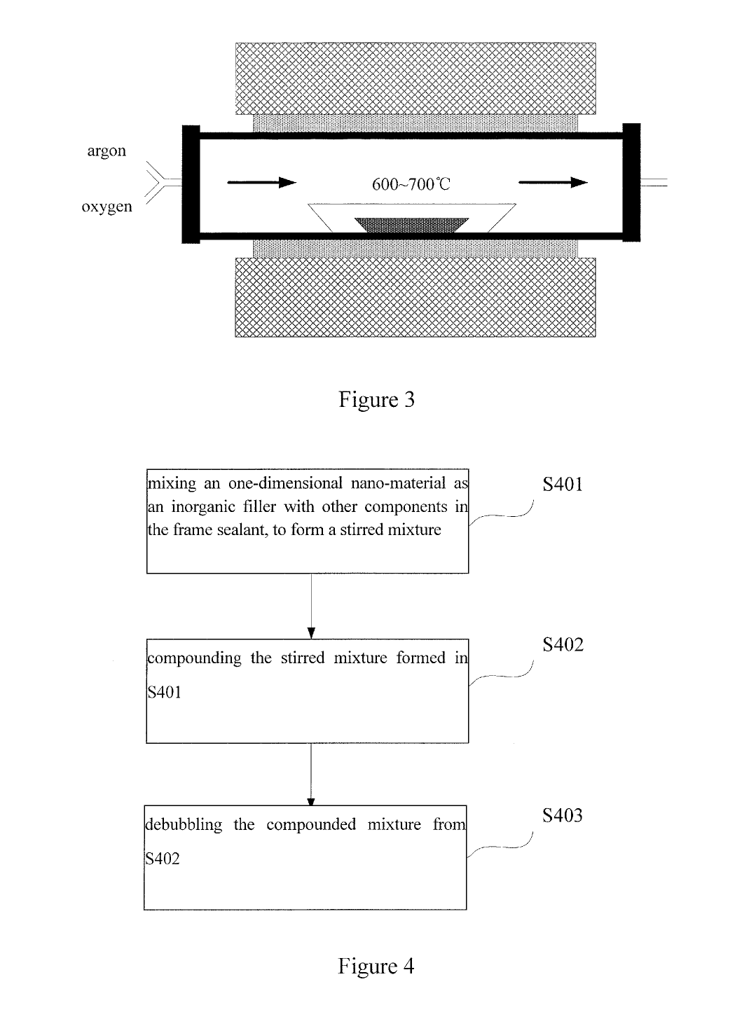

In the example of the present invention, zinc oxide nanowires are preferably prepared from zinc powders with the addition of an amount of manganese oxide powders by a chemical vapor deposition process. As shown in FIG. 3, zinc powders and manganese oxide powders are mixed and evenly laid on the bottom of a porcelain boat. A cleansed silicon chip is fixed above the porcelain boat. The temperature is set at 600-700° C. A mixed gas of oxygen and argon is passed into the tube, where argon is in a flow rate of 300-320 cm³·min⁻¹ and oxygen is in a flow rate of 10-15 cm³·min⁻¹. The reaction is carried out for 20-40 min, to produce a mass of one-dimensional wire-like zinc oxide nano-structure. The zinc oxide nanowires thus produced have a diameter of 5-20 nm and a length of 50-500 nm.

Further, in the example of the present invention, zinc oxide nanowires as the inorganic filler are preferably in 10-20 wt %. For example, it can be 10 wt %, 12 wt %, 13 or 15 wt %, 18 wt %, 20 wt %, preferably, 15 wt %.

Particularly, in the example of the present invention, the components in the frame sealant can be in the composition shown in the following table. It should be understood that such compositions are intended to illustrate rather than limit and those compositions within the range as descried here are all acceptable.

| | |
|---|---|
| Epoxy-acrylic resin | 25% |
| acrylic resin | 35% |
| Thermal curing agent | 15% |
| Coupling agent | 4.5% |
| Photoinitiator | 0.5% |
| Organic filler | 5% |
| Zinc oxide nanowires | 15% |

In the example of the present invention, the frame sealant comprising the components in the ratios as shown in the above table can reduce the ratio of undesirable precipitation to 0%. The frame sealants comprising silica nano-particles as filler typically have a ratio of undesirable precipitation of 2% or so. Therefore, the frame sealant of the example of the present invention can well prevent granular materials from precipitating, improve the undesirable precipitation during curing, and enhance the display quality.

### Example 2

The example of the present invention further provides a display device, comprising an array substrate and a color film substrate cell assembled, between which the frame sealant of Example 1 is provided.

The display device in the example of the present invention can be any display product or device which has display function, including without limitation a liquid crystal panel, electronic paper, an organic light emitting diode (OLED) panel, a cell phone, a tablet PC, a TV, a display, a laptop, a digital photo frame, and a navigator.

In the display device of the example, the frame sealant provided between the color film substrate and the array substrate comprises an one-dimensional nano-material capable of cross-linking with an epoxy-acrylic resin. The cross-linking reaction occurring between the one-dimensional nano-material and the epoxy-acrylic resin will lead to the formation of an interlaced network, which can prevent granular materials from precipitating and improve the display quality.

### Example 3

Example 3 of the present invention further provides a method of preparing a frame sealant, as shown in FIG. 4, comprising:

S401: mixing an one-dimensional nano-material as an inorganic filler with other components in the frame sealant, to form a stirred mixture.
Particularly, mixing 10-20 wt % (particularly, 10%, 12%, 13% or 15%, 18%, 20%) of an one-dimensional nano-material, 20-30 wt % (particularly, 20%, 22%, 23% or [symbol] 25%, 28%, 30%) of an epoxy-acrylic resin, 30-40 wt % (particularly, 30%, 32%, 33% or 35%, 38%, 40%) of an acrylic resin, 10-20 wt % (particularly, 10%, 12%, 13% or 15%, 18%, 20%) of a thermal curing agent, 4-5 wt % of a coupling agent, 0.1-1wt % (particularly, 0.1%, 0.2%, 0.3% or 0.5%, 0.8%, 1%) of a photoinitiator, and 1-10 wt % (particularly, 1%, 2%, 3% or 5%, 8%, 10%) of an organic filler for 30-60 min at a temperature of 10-30° C., to form a stirred mixture;

In the example of the present invention, the one-dimensional nano-material contained in the inorganic filler can cross-link with the epoxy-acrylic resin in the frame sealant to form an interlaced network, which can prevent granular materials from precipitating and improve the display quality.

Further, in the present example the process of forming a stirred mixture can preferably comprise:
stirring 25 wt % of the epoxy-acrylic resin, 35 wt % of the acrylic resin, 5 wt % of the epoxy-acrylic resin, 15 wt % of the thermal curing agent, 4.5 wt % of the coupling agent, 0.5wt % of the photoinitiator, and 5 wt % of the organic filler, and 15 wt % of zinc oxides nanowires, for 30-60 min at a temperature of 10-30° C., to form a stirred mixture.

Preferably, the one-dimensional nano-materials are zinc oxide nanowires. Of course, it can be other one-dimensional nano-materials and is not particularly limited. For example, the one-dimensional nano-material also can be carbon nanowires.

When zinc oxide nanowires are preferred as one-dimensional nano-material, the method further comprises, prior to forming the stirred mixture:
preparing the zinc oxide nanowires from zinc powder and manganese oxide powder by a chemical vapor deposition process.

The particular process of preparing the zinc oxide nanowires can be referred to FIG. 3. Zinc powders and manganese oxide powders are mixed in a weight ratio of 9:1 and evenly laid on the bottom of a porcelain boat. A cleansed silicon chip is fixed above the porcelain boat. The temperature is set at 600-700° C. A mixed gas of oxygen and argon is continuously passed into the tube. The reaction is continued for 30 min to produce zinc oxide nanowires having a diameter of 5-20 nm and a length of 50-500 nm.

Further, at a temperature of 600-700° C., argon is controlled to have a flow rate of 300-320 cm³·min⁻¹ and oxygen is controlled to have a flow rate of 10-15 cm³·min⁻¹, to produce a mass of one-dimensional wire-like zinc oxide nano-structure.

S402: compounding the stirred mixture formed in S401.
Particularly, the stirred mixture from S401 will be compounded at a temperature of 30-50° C.

S403: debubbling the compounded mixture from S402.
Particularly, in the present example, the compounded mixture from S402 can be debubbled in a SIENOX debubbler.

In method of preparing the frame sealant in the present example, the inorganic filler comprises one-dimensional material, which mixes with other components in the frame sealant, undergoes the compounding and debubbling process to produce the frame sealant. During the curing of the frame sealant, the one-dimensional nano-material will cross-link with the epoxy-acrylic resin to form an interlaced network, which can prevent granular materials from precipitating and improve the display quality.

It is apparent that person of ordinary skill in the art can make various modifications and variations to the present invention without departing from the spirit and scope of the present invention. Thus, provided that such modifications and variations of the present invention are encompassed by the appended claims and the equivalents thereof, the present invention is also intended to encompass these modifications and variations.

1. A frame sealant comprising an epoxy-acrylic resin, an acrylic resin, a thermal curing agent, a coupling agent, a photoinitiator, and an organic filler, wherein the frame sealant further comprises an one-dimensional nano-material as an inorganic filler which is capable of cross-linking with the epoxy-acrylic resin.

2. The frame sealant of claim 1, wherein the one-dimensional nano-material is zinc oxide nanowires.

3. The frame sealant of claim 1, wherein the one-dimensional nano-material is 10-20% by weight.

4. The frame sealant of claim 2, wherein the zinc oxide nanowires have an outer diameter of 5-20 nm and a length of 50-500 nm.

5. A display device, comprising an array substrate and a color film substrate cell assembled, wherein the frame sealant of claim 1 is provided between the array substrate and the color film substrate.

6. A method of preparing the frame sealant of claim 1, comprising:
mixing 10-20 wt % of an one-dimensional nano-material 20-30 wt % of an epoxy-acrylic resin, 30-40 wt % of an acrylic resin, 10-20 wt % of a thermal curing agent, 4-5 wt % of a coupling agent, 0.1-1 wt % of a photoinitiator, and 1-10 wt % of an organic filler for 30-60 min at a temperature of 10-30° C., to form a stirred mixture;
compounding the stirred mixture;
debubbling the compounded mixture.

7. The method of claim 6, wherein the one-dimensional nano-material is zinc oxide nanowires.

8. The method of claim 7, wherein, prior to forming the stirred mixture, the method further comprises:
preparing the zinc oxide nanowires from zinc powder and manganese oxide powder by a chemical vapor deposition process.

9. The method of claim 8, wherein, preparing the zinc oxide nanowires from zinc powder and manganese oxide powder by a chemical vapor deposition process comprises:
continuously passing a mixed gas of oxygen and argon into zinc powder and manganese oxide powder in a weight ratio of 9:1 at a temperature of 600-700° C. for reacting for 20-40 min, to produce the zinc oxide nanowires.

10. The method of claim 9, wherein, argon is passed in a flow rate of 300-320 cm³·min⁻¹ and oxygen is passed in a flow rate of 10-15 cm³·min⁻¹.

11. The frame sealant of claim 2, wherein the one-dimensional nano-material is 10-20% by weight.
